(19) United States
(12) Patent Application Publication
(10) Pub. No.: US 2016/0154061 A1
(43) Pub. Date: Jun. 2, 2016

(54) METHOD OF ASSESSING RISK OF POWER SYSTEM WITH HIGH PENETRATION OF WIND POWER

(71) Applicants: State Grid Corporation of China, Beijing (CN); Gansu Electric Power Company of State Grid, Lanzhou (CN); Tsinghua University, Beijing (CN); Wind Power Technology Center of Gansu Electric Power Company, Lanzhou (CN)

(72) Inventors: NING-BO WANG, Beijing (CN); LIANG LU, Beijing (CN); ZONG-XIANG LU, Beijing (CN); YING QIAO, Beijing (CN); QING-QUAN LV, Beijing (CN); LONG ZHAO, Beijing (CN)

(21) Appl. No.: 14/684,453

(22) Filed: Apr. 13, 2015

(30) Foreign Application Priority Data
Nov. 28, 2014 (CN) 201410701366.1

(51) Int. Cl. G01R 31/34; G06Q 50/06

(52) U.S. Cl. CPC G01R 31/34; G06Q 50/06

(57) ABSTRACT

A method of assessing risk of power system with high penetration of wind power includes following steps. A correlation coefficient between wind power and load is obtained, and a probability of negative peak shaving is calculated. A probability of extreme ramp rate under extreme weather conditions is obtained, wherein a probability distribution of the extreme ramp rate matches principles of HILF and LIHF. A PRNS, an ERNS, and a RI are obtained, optimal reserve demand is obtained utilizing Unit Commitment Model, and operation risk based on PRNS, ERNS, and RI is calculated. A relationship between frequency and consequence distribution of risk is obtained by calculating the operation risks during N days, dividing the operation risks into different risk levels, and calculating a frequency of each risk level, wherein the operation risks in each level have similar values.

### CROSS-REFERENCE TO RELATED APPLICATIONS

This application claims all benefits accruing under 35 U.S.C. §119 from China Patent Application 201410701366.1, filed on Nov. 28, 2014 in the China Intellectual Property Office, the disclosure of which is incorporated herein by reference.

### BACKGROUND

1. Technical Field

The present disclosure relates to a method of assessing risk of power system with high penetration of wind power, especially for a method of assessing risk of power system with high penetration of wind power considering negative peak shaving and extreme weather conditions.

2. Description of the Related Art

Wind power has been developed rapidly in recent years. Statistics show that the new installed wind power capacity has been up to 45 GW in 2012, which has increased 10% more than 2011. The accumulate wind power capacity has reached 2825 GW all over the world till the end of 2012 and has increased 9% more than 2011. The operation risk significantly increases due to high penetration of wind generations.

What is needed, therefore, is a method of assessing risk of power system with high penetration of wind power that can overcome the above-described shortcomings.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 shows a flow chart of one embodiment of a method of assessing risk of power system with high penetration of wind power.

FIG. 2 shows a schematic view of one embodiment of a probability distribution of correlation coefficient between wind power and load.

FIG. 3 shows a schematic view of one embodiment of a probability of ramp rate of wind power.

FIG. 4 shows a schematic view of one embodiment of an optimal reserve demand of case A, B and C.

FIG. 5 shows a scatter diagram of one embodiment of a frequency and consequence distribution of risk.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

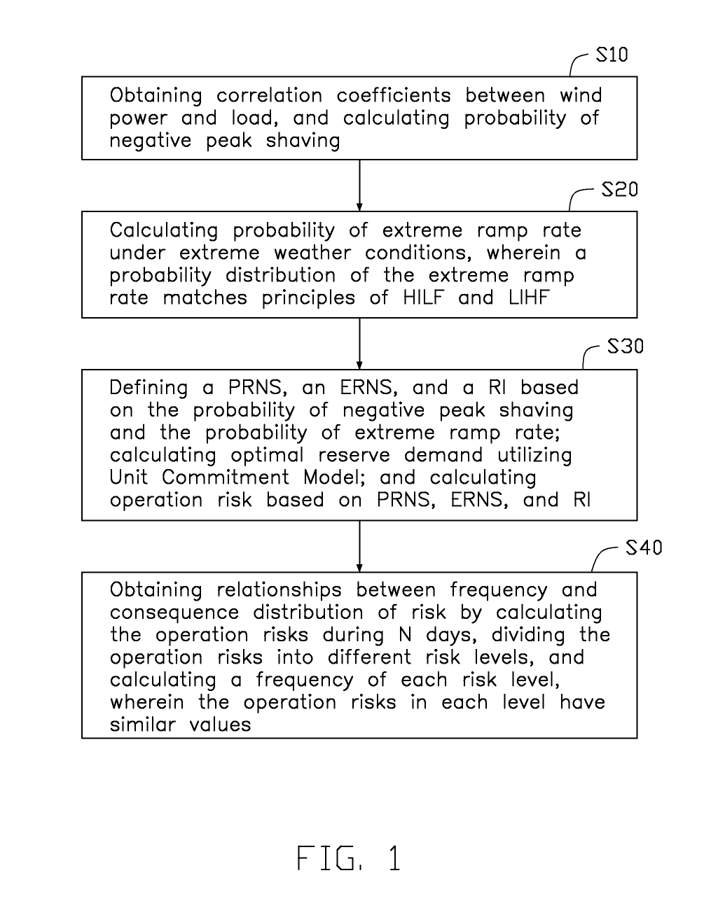

Referring to FIG. 1, a method of assessing risk of power system with high penetration of wind power comprises following steps:

step (S10), obtaining correlation coefficients between wind power and load, and calculating probability of negative peak shaving;

step (S20), calculating probability of extreme ramp rate under extreme weather conditions, wherein a probability distribution of the extreme ramp rate matches principles of High Impact and Low Frequency (HILF) and Low Impact and High Frequency (LIHF);

step (S30), defining a probability of ramp rate not satisfy (PRNS), an expectation of ramp rate not satisfy (ERNS), and a relative reserve increment (RI) based on the probability of negative peak shaving and the probability of extreme ramp rate; calculating optimal reserve demand utilizing Unit Commitment Model (UC); and calculating operation risk based on PRNS, ERNS, and RI;

step (S40), obtaining relationships between frequency and consequence distribution of risk by calculating the operation risks during N days, dividing the operation risks into different risk levels, and calculating a frequency of each risk level, wherein the operation risks in each level have similar values.

In step (S10), the correlation coefficients between wind power and load can be obtained based on the formula (1):

$$r = \frac{{\sum }_{i = 1}^{n} ( {x}_{i} - \overline{x} ) ( {y}_{i} - \overline{y} )}{\sqrt{{\sum }_{i = 1}^{n} {( {x}_{i} - \overline{x} )}^{2} {\sum }_{i = 1}^{n} {( {y}_{i} - \overline{y} )}^{2}}} . \qquad ( 1 )$$

The probability of negative peak shaving can be obtained by dividing the correlation coefficients into groups by the interval of 0.1.

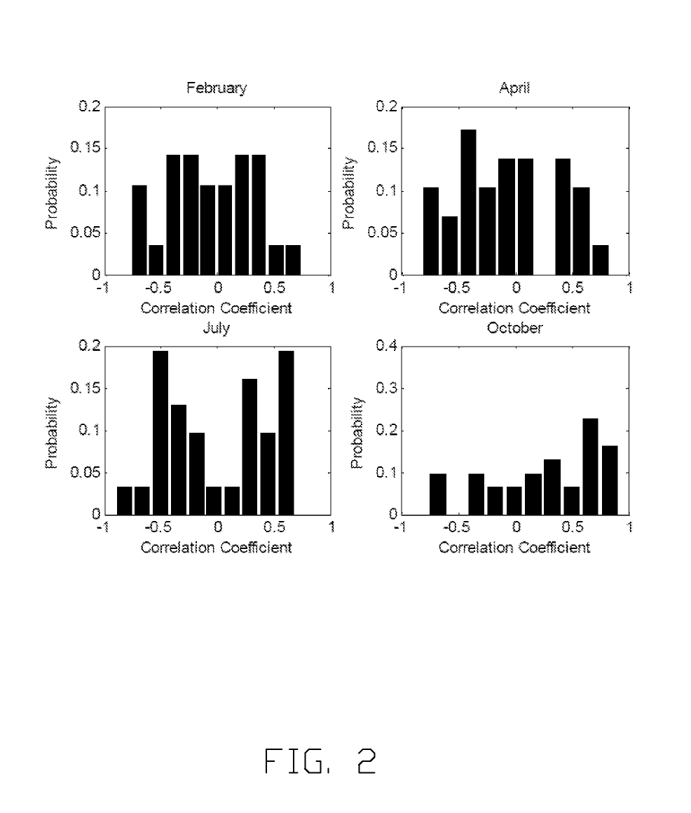

Referring to FIG. 2, the correlation coefficients are negative, which indicate that the probability of negative peak shaving is greater than peak shaving in most seasons except the winter.

In step (S20), the extreme ramp rates Ramp(t,T) can be obtained based on formula (2):

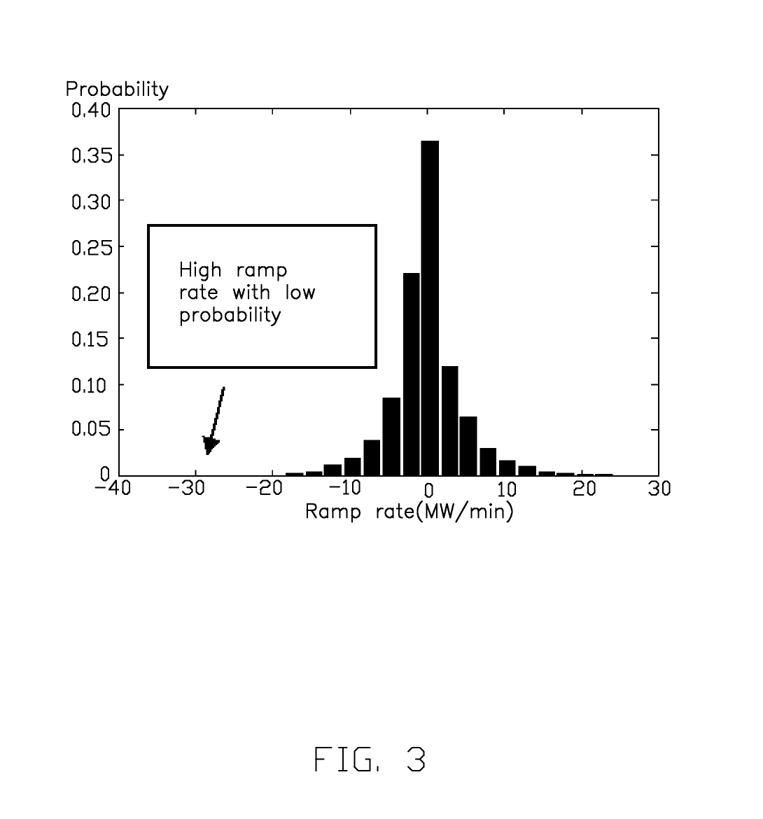

Ramp(t,T)=(P_{W}(t+T)−P_{W}(t))/T (2);

wherein t represents operation time, T represents scheduling interval, and P_{w} represents output power of wind farm. The probability distribution of extreme ramp rates is shown in FIG. 3.

In step (S30), in order to assessing the operation risk of the power system, the PRNS, the ERNS, and the RI based on the probability of negative peak shaving and the probability of extreme ramp rate in step (S10) and (S20). The PRNS, the ERNS, and the RI can be obtained by:

$$\begin{matrix}P R N S = \frac{1}{N} {\sum }_{t = 1}^{N} {I}_{t} ; & ( 3 ) \\ E R N S = \frac{1}{N} {\sum }_{t ∈ F} {I}_{t} \times {R}_{t} ; & ( 4 ) \\ R I = {\sum }_{t = 1}^{N} ( {R}_{u}^{t} + {R}_{d}^{t} - {R}_{u 0}^{t} - {R}_{d 0}^{t} ) / {P}_{L max} ; & ( 5 )\end{matrix}$$

wherein Iₜ is a binary variable at time t representing if the ramp rate satisfies (equal to 0) or not (equal to 1), and N denotes the number of time in simulation period. Rₜ denotes the ramp rate shortage at time t. R^{t}ᵤ₀, R^{t}_{d0}, R^{t}ᵤ, and R^{t}_{d} represent the up and down reserve demand before and after the wind power integration respectively at time t, P_{Lmax} corresponds to the maximum load.

The reserve demand F can be calculated through formula (6):

$$\begin{matrix}F = w \times F + {w}_{wind} \times {f}_{wind} + {w}_{load} \times {f}_{load} + {w}_{R} \times {f}_{R} \\ = {\sum }_{t = 1}^{T} ( \begin{matrix}( {\sum }_{i = 1}^{{N}_{G}} w {f}_{i} ( {P}_{Gi}^{t} ) + {w}_{R} {\sum }_{i = 1}^{{N}_{G}} ( {R}_{ui}^{t} + {R}_{di}^{t} ) ) + \\ {w}_{load} {P}_{C}^{t} + {\sum }_{j = 1}^{{N}_{W}} {w}_{wind} ( {P}_{Wjmax}^{t} - {P}_{Wj}^{t} )\end{matrix} )\end{matrix}$$

wherein f denotes the fuel cost of conventional units; f_{wind} and f_{load} represent the punishment of wind power curtailment and load shedding respectively; f_{R} means the reserve cost; w and w_{R} denote the price of fuel and reserve respectively; w_{wind} and w_{load} represent the penalty coefficients of wind power curtailment and load shedding respectively.

In step (S40), the operation risks can be divided by:

step (S41), arranging the operation risks during N days in ascending order R₁<R₂< . . . < Rₙ;

step (S42), dividing [R₁, Rₙ] into m levels according to requirement of accuracy;

step (S43), calculating a number of operation risks nᵢ in each level, wherein nᵢ is defined as the frequency of each level.

### EMBODIMENT

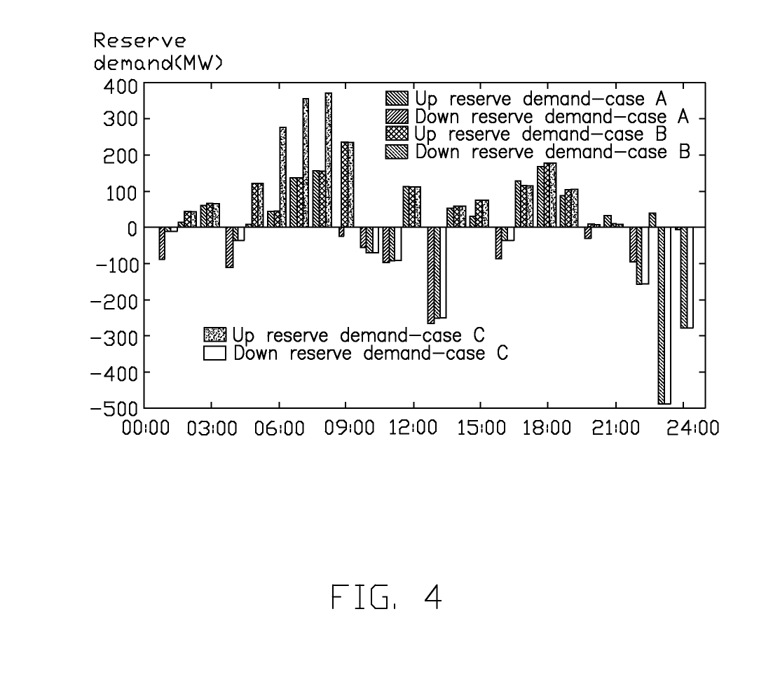

Three cases are studied in this section. Case A, B and C are representing the scenario without wind power, with wind power in normal weather, and extreme weather condition respectively. PRNS and ERNS are used as the indices to assess the risk. Case A is a benchmark, whose optimal reserve demand is calculated by the UC model with the result shown in FIG. 4.

If the reserves in case B and C are the same with case A, assuming the probability of the extreme weather is 0.01, the risk indices can be calculated in TABLE 1.

TABLE 1
THE RISK INDICES IN CASE A, B AND C

| Case scenario | PRNS | ERNS(MW/15 min) |
|---|---|---|
| A(benchmark) | 0 | 0 |
| B | 0.5625 | 60.71 |
| C | 0.0044 | 71.57 |

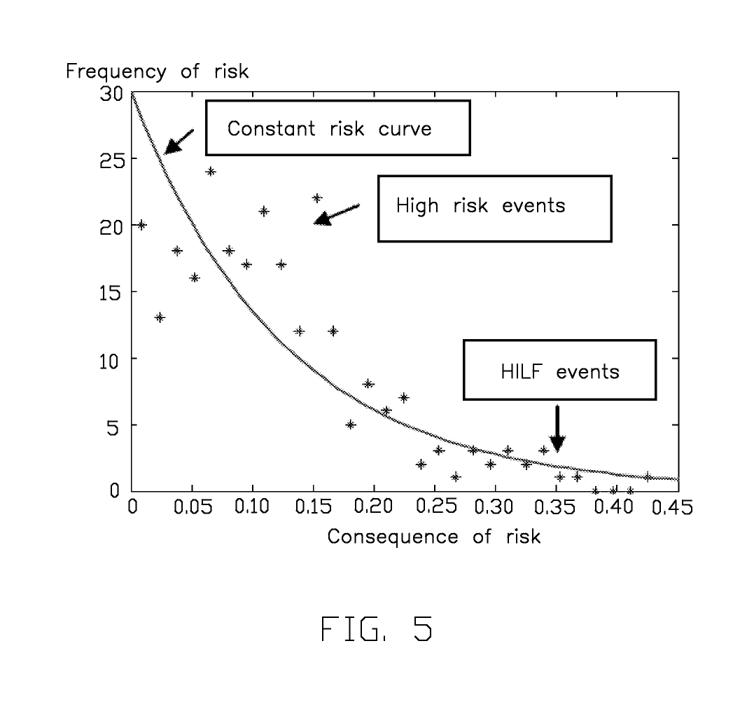

Table 1 shows that the risk indices increases obviously in case B and C compared with A. The additional reserve capacity should be input to maintain the original risk level. Apply the UC model to calculate the optimal reserve demand of case B and C, as is shown in FIG. 5.

The method of assessing risk of power system with high penetration of wind power has following advantages. Firstly, the characters of negative peak shaving and extreme ramp rate are analyzed to elaborate the risk. Secondly, the risk indices are defined and the UC model is applied to get the optimal reserve increment. Finally, the character of risk indices in terms of frequency and consequence is studied, and the scatter diagram can be obtained. Thus the risk of power system can be accurately assessed. Furthermore, the risk assessment can provide important reference for the power system maintenance, and the operation of the power system can be guaranteed.

Depending on the embodiment, certain of the steps of methods described may be removed, others may be added, and that order of steps may be altered. It is also to be understood that the description and the claims drawn to a method may include some indication in reference to certain steps. However, the indication used is only to be viewed for identification purposes and not as a suggestion as to an order for the steps.

It is to be understood that the above-described embodiments are intended to illustrate rather than limit the disclosure. Variations may be made to the embodiments without departing from the spirit of the disclosure as claimed. It is understood that any element of any one embodiment is considered to be disclosed to be incorporated with any other embodiment. The above-described embodiments illustrate the scope of the disclosure but do not restrict the scope of the disclosure.

What is claimed is:

1. A method of assessing risk of power system with high penetration of wind power, the method comprising:
obtaining correlation coefficients between a wind power and a load, and calculating a probability of negative peak shaving;
calculating a probability of an extreme ramp rate under extreme weather conditions, wherein a probability distribution of the extreme ramp rate matches principles of High Impact and Low Frequency (HILF) and Low Impact and High Frequency (LIHF);
defining a probability of ramp rate not satisfy (PRNS), an expectation of ramp rate not satisfy (ERNS), and a relative reserve increment (RI) based on the probability of negative peak shaving and the probability of extreme ramp rate, calculating optimal reserve demand utilizing Unit Commitment Model, and calculating operation risk based on PRNS, ERNS, and RI; and
obtaining relationships between frequency and consequence distribution of risk by calculating the operation risks during N days, dividing the operation risks into different risk levels, and calculating a frequency of each risk level; wherein the operation risks in each level have similar values.

2. The method of claim 1, wherein the correlation coefficients between the wind power and the load is obtained based on:
$$r = \frac{{\sum }_{i = 1}^{n} ( {x}_{i} - \overline{x} ) ( {y}_{i} - \overline{y} )}{\sqrt{{\sum }_{i = 1}^{n} {( {x}_{i} - \overline{x} )}^{2} {\sum }_{i = 1}^{n} {( {y}_{i} - \overline{y} )}^{2}}} .$$

3. The method of claim 2, wherein the probability of negative peak shaving is obtained by dividing the correlation coefficients into groups by the interval of 0.1.

4. The method of claim 1, wherein the extreme ramp rates Ramp(t,T) is obtained by:
Ramp(t,T)=(P_{W}(t+T)−P_{W}(t))/T;
wherein t represents an operation time, T represents a scheduling interval, and P_{w} represents an output power of wind farm.

5. The method of claim 1, wherein the PRNS, the ERNS, and the RI is obtained by:
$$\begin{matrix}P R N S = \frac{1}{N} {\sum }_{t = 1}^{N} {I}_{t} ; \\ E R N S = \frac{1}{N} {\sum }_{t ∈ F} {I}_{t} \times {R}_{t} ; \\ R I = {\sum }_{t = 1}^{N} ( {R}_{u}^{t} + {R}_{d}^{t} - {R}_{u 0}^{t} - {R}_{d 0}^{t} ) / {P}_{L max} ;\end{matrix}$$
wherein Iₜ is a binary variable at time t representing if the ramp rate satisfies (equal to 0) or not (equal to 1), and N denotes the number of time in simulation period; Rₜ denotes a ramp rate shortage at time t; R^{t}ᵤ₀ represents an up reserve demand before a wind power integration, R^{t}_{d0}, represents a down reserve demand before the wind power integration, R^{t}ᵤ represents an up reserve demand after the wind power integration, and R^{t}ᵤ represent the up and down reserve demand after the wind power integration at time t, P_{Lmax} corresponds to the maximum load.

6. The method of claim 5, wherein the reserve demand F is calculated through:
$$\begin{matrix}F = w \times F + {w}_{wind} \times {f}_{wind} + {w}_{load} \times {f}_{load} + {w}_{R} \times {f}_{R} \\ = {\sum }_{t = 1}^{T} ( \begin{matrix}( {\sum }_{i = 1}^{{N}_{G}} w {f}_{i} ( {P}_{Gi}^{t} ) + {w}_{R} {\sum }_{i = 1}^{{N}_{G}} ( {R}_{ui}^{t} + {R}_{di}^{t} ) ) + \\ {w}_{load} {P}_{C}^{t} + {\sum }_{j = 1}^{{N}_{W}} {w}_{wind} ( {P}_{Wjmax}^{t} - {P}_{Wj}^{t} )\end{matrix} )\end{matrix}$$
wherein f denotes a fuel cost of conventional units; f_{wind} and f_{load} represent the punishment of wind power curtailment and load shedding respectively; f_{R} represents a reserve cost; w and w_{R} denote a price of fuel and a price of reserve respectively; w_{wind} and w_{load} represent a penalty coefficients of wind power curtailment and a penalty coefficients of load shedding respectively.

7. The method of claim 1, wherein the dividing the operation risks comprises:
arranging the operation risks during N days in ascending order R₁<R₂< . . . <Rₙ;
dividing [R₁, Rₙ] into m levels according to requirement of accuracy; and
calculating a number of operation risks nᵢ in each level, wherein nᵢ is defined as the frequency of each level.
